(19) United States
(12) Patent Application Publication
(10) Pub. No.: US 2025/0212672 A1
(43) Pub. Date: Jun. 26, 2025

(54) Light Emitting Display Device

(71) Applicant: LG Display Co., Ltd., Seoul (KR)

(72) Inventors: Wonjong Cho, Paju-si (KR); Jinhyung Jung, Paju-si (KR); Huyngguen Kim, Paju-si (KR)

(21) Appl. No.: 18/916,468

(22) Filed: Oct. 15, 2024

(30) Foreign Application Priority Data
Dec. 20, 2023 (KR) 10-2023-0187045

(51) Int. Cl. H10K 59/80

(52) U.S. Cl. CPC H10K 59/8794

(57) ABSTRACT

The present disclosure relates to a light emitting display device having a heat dissipation structure. A light emitting display device comprises: a substrate; a display layer on the substrate; a protective layer under the substrate; a heat insulating layer under the protective layer; a heat dissipation layer under the heat insulating layer; and a driving element under the heat dissipation layer.

### CROSS-REFERENCE TO RELATED APPLICATION

This application claims the benefit of the Republic of Korea Patent Application No. 10-2023-0187045 filed on Dec. 20, 2023, which is hereby incorporated by reference in its entirety.

### BACKGROUND

### Field of Technology

The present disclosure relates to a light emitting display device having a heat dissipation structure.

### Discussion of the Related Art

In modern society, a wide variety of electronic devices are used, such as televisions, monitors, laptop computers, smart phones, tablet computers, electronic pads, wearable devices, and navigation devices. These electronic devices are implemented as multimedia devices with complex functions such as video display, video shooting, music and video file playback, games and broadcast system. These electronic devices may include a display panel and a driving circuit element connected to drive the display panel.

Although these electronic devices may generate heat in the display panel, more heat generation problems occur in the driving circuit elements. In particular, for the light emitting display panels that implement ultra-high resolution of 4 K ppi (pixel per inch) or higher, excessive heat may be generated from the driving circuit elements that supply data information to each pixel and the display panel itself that displays images. Moreover, the heat generated form the display panel and the heat generated from the driving circuit elements may be transferred to each other, which may adversely affect the function and lifespan of the entire display device.

Therefore, there is a need to develop a structure for a light emitting display device that simultaneously has a heat dissipation structure that quickly discharges the heat generated from the display panel and the driving circuit elements to the outside and a heat insulation structure that prevents heat exchange between them.

### SUMMARY

The purpose of the present disclosure, as for solving the problems described above, is to provide a heat dissipation structure that may quickly discharge the heat generated from the display panel and driving circuit elements in ultra-high-resolution light emitting display device to the outside.

The purpose of the present disclosure is to provide an ultra-high resolution light emitting display devices having heat insulation structure that prevents heat generated from the display panel and heat generated from the driving circuit elements from being exchanged and causing problems to the entire light emitting display device.

In one embodiment, a light emitting display device comprises: a substrate; a display layer on the substrate; a protective layer under the substrate; a heat insulating layer under the protective layer; a heat dissipation layer under the heat insulating layer; and a driving element under the heat dissipation layer.

In one embodiment, the heat insulating layer prevents first heats generated from the display layer from being transferred to the driving element, and prevents second heats generated from the driving element from being transferred to the display layer.

In one embodiment, the heat dissipation layer discharges heats generated from the driving element outside through a horizontal surface direction of the substrate.

In one embodiment, the heat insulating layer includes: a metal layer under the heat insulating layer; and a thermal conductive adhesive layer under the metal layer.

In one embodiment, the thermal conductive adhesive layer transfers the heats generated from the driving element to the metal layer. The metal layer discharges the heats transferred from the thermal conductive adhesive layer outside along a horizontal surface direction of the substrate.

In one embodiment, the metal layer includes aluminum. The thermal conductive adhesive layer includes a filler and a silicon-based resin with a volume content ratio in range of 8:2 to 9:1. The filler includes alumina particles and silicon nitride particles with a volume content ratio of 8:2.

In one embodiment, the light emitting display device further comprises: a thermal conductive cover layer on the display layer.

In one embodiment, the thermal conductive cover layer includes a filler and a silicon-

based resin with a volume content ratio in range of 8:2 to 9:1. The filler includes alumina particles and silicon nitride particles with a volume content ratio of 8:2.

In one embodiment, the heat insulating layer includes: a first non-thermal conductive adhesive layer under the protective layer; a shock absorbing layer under the first non-thermal conductive adhesive layer; and a second non-thermal conductive adhesive layer under the shock absorbing layer.

In one embodiment, each of the first non-thermal conductive adhesive layer and the second non-thermal conductive adhesive layer includes a filler and an acryl-based resin with a volume content ratio in range of 3:7 to 6:4. The filler includes alumina particles and silicon nitride particles with a volume content ratio of 2:8.

In one embodiment, the light emitting display device further comprises: a thermal conductive cover layer on the display layer. The heat dissipation layer includes: a metal layer under the heat insulating layer; and a thermal conductive adhesive layer under the metal layer. The heat insulating layer includes: a first non-thermal conductive adhesive layer under the protective layer; a shock absorbing layer under the first non-thermal conductive adhesive layer; and a second non-thermal conductive adhesive layer under the shock absorbing layer.

In one embodiment, the light emitting display device further comprises: a heat dissipation element disposed to the driving element.

In one embodiment, the heat dissipation element includes a filler and a silicon-based resin with a volume content ratio in range of 8:2 to 9:1. The filler including alumina particles and silicon nitride particles with a volume content ratio of 8:2.

In one embodiment, the heat dissipation element includes: a base portion; and a pattern portion including a plurality of patterns arrayed with a predetermined interval on the base portion.

In one embodiment, the pattern portion includes a cross-sectional shape any one shape of triangle, rectangle and semicircle.

The light emitting display according to the present disclosure may quickly discharge heat generated from the display panel and driving circuit elements to the outside. Additionally, heat generated from the display panel may be prevented from affecting the driving circuit elements. Further, heat generated from the driving circuit elements may be prevented from affecting the display panel.

Accordingly, the light emitting display device according to the present disclosure may prevent damage caused by self-heat generated from the elements configuring the device. Additionally, the present disclosure may safely secure the reliability of a light emitting display device and provide a light emitting display device with a long service life.

In addition to the effects of the present disclosure mentioned above, other features and advantages of the present disclosure are described below, and from such description, it will be clearly understood by those skilled in the art to which the present disclosure belongs.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plane view illustrating a schematic structure of a light emitting display according to an embodiment of the present disclosure.

FIG. 2 is an equivalent circuit diagram illustrating a structure of one pixel included in the light emitting display of FIG. 1 according to an embodiment of the present disclosure.

FIG. 3 is an enlarged plane view illustrating the structure of one pixel in the light emitting display device of FIG. 1 according to an embodiment of the present disclosure.

FIG. 4 is a cross-sectional view along cutting line II-II′ in FIG. 2 that illustrates a structure of the light emitting display according to an embodiment of the present disclosure.

FIG. 5 is a side view along cutting line I-I′ in FIG. 1 that illustrates a structure of the light emitting display device according to an embodiment of the present disclosure.

FIG. 6 is a diagram illustrating a structure of a non-thermally conductive material and a thermally conductive material, and the thermal conductivity of each of these materials according to an embodiment of the present disclosure.

FIG. 7 is an enlarged cross-sectional view of square dotted area ‘X’ in FIG. 5 that, illustrates a structure of the light emitting display device according to a first embodiment of the present disclosure.

FIG. 8 is an enlarged cross-sectional view of square dotted area ‘X’ in FIG. 5 that illustrates a structure of the light emitting display device according to a second embodiment of the present disclosure.

FIG. 9 is an enlarged cross-sectional view of square dotted area ‘X’ in FIG. 5 that illustrates a structure of the light emitting display device according to a third embodiment of the present disclosure.

FIG. 10 is an enlarged cross-sectional view of square dotted area ‘X’ in FIG. 5 that illustrates a structure of the light emitting display device according to a fourth embodiment of the present disclosure.

FIG. 11 is an enlarged cross-sectional view of square dotted area ‘X’ in FIG. 5 that illustrates a structure of the light emitting display device according to a fifth embodiment of the present disclosure.

FIG. 12 is a cross-sectional view illustrating a form of a heat dissipation element according to another example of the light emitting display device shown in FIG. 11.

FIG. 13 is a cross-sectional view illustrating a form of a heat dissipation element according to still another example of the light emitting display device shown in FIG. 11.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts. Since a scale of each of elements shown in the accompanying drawings may be different from an actual scale for convenience of description, the present disclosure is not limited to the scale shown in the drawings.

Hereinafter, referring to the attached figures, the present disclosure will be explained. Since a scale of each of elements shown in the accompanying drawings may be different from an actual scale for convenience of description, the present disclosure is not limited to the scale shown in the drawings.

Hereinafter, referring to FIG. 1, a light emitting display device according to an embodiment of the present disclosure will be explained. FIG. 1 is a plane view illustrating a schematic structure of a light emitting display device according to an embodiment of the present disclosure. In FIG. 1, the X-axis refers to the direction parallel to the scan line, the Y-axis refers to the direction of the data line, and the Z-axis refers to the height direction of the display device.

Referring to FIG. 1, a light emitting display comprises a substrate 110, a gate (or scan) driver 200, a pad portion 300, a source driving IC (integrated circuit) 410, a flexible film 430, a circuit board 450, and a timing controller 500.

The substrate 110 may include an electrical insulating material or a flexible material. The substrate 110 may be made of a glass, a metal or a plastic, but it is not limited thereto. When the electroluminescence display is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. The display area AA includes a plurality of pixels P arrayed in a matrix manner. The display area AA further includes scan lines 50 (or gate lines) and data lines 60. One pixel P is disposed at a position where the scan lines 50 running along X-axis and the data lines 60 running along Y-axis are crossing each other.

Here, pixel P may represent one color selected from red, green and blue or red, green, blue and white. A red pixel, a green pixel and a blue pixel may be gathered together, or a red pixel, a green pixel, a blue pixel and a white pixel may be gathered together to form one unit-pixel.

The non-display area NDA, which is an area not representing the video images, may be defined at the circumference areas of the substrate 110 surrounding all or some of the display area DA. In the non-display area NDA, a low-potential line 80, the gate driver 200 and the data pad portion 300 may be formed or disposed.

The gate driver 200 may supply the scan (or gate) signals to the scan lines according to the gate control signal received from the timing controller 500 through the pad portion 300. The gate driver 200 may be formed at the non-display area NDA at one outside or both outsides of the display area AA on the substrate 110, as a GIP (Gate driver In Panel) type. GIP type means that the gate driver 200 is directly formed on the substrate 110. For example, the gate driver 200 may include a plurality of shift registers. The GIP method refers to a structure in which the transistors included into the shift register of the gate driver 200 are formed directly on the substrate 110.

The pad portion 300 may be disposed in the non-display area NDA at one edge of the display area AA of the substrate 110. The pad portion 300 may include data pads 61 connected to each of the data lines 60, driving current pads 71 connected to each of the driving current lines 70. Even though it is not shown in figures, the pad portion 300 may further include a high-potential pad receiving a high potential voltage, and a low-potential pad receiving a low potential voltage.

The source driving IC 410 may receive the digital video data and the source control signal from the timing controller 500. The source driving IC 410 may convert the digital video data into the analog data voltages according to the source control signal and then supply that to the data lines 60. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible film 430.

The circuit board 450 may be attached to the flexible circuit film 430. For example, using an anisotropic conducting film, the lines of the flexible circuit film 430 may be connected to the lines of the circuit board 450. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

TV monitor, computer monitor, laptop monitor or tablet display device may be manufactured using a light emitting display device as shown in FIG. 1. At this time, the flexible circuit film 430 may be bent to place or attach the source driving IC 410 and the circuit board 450 to the backside of the substrate 110.

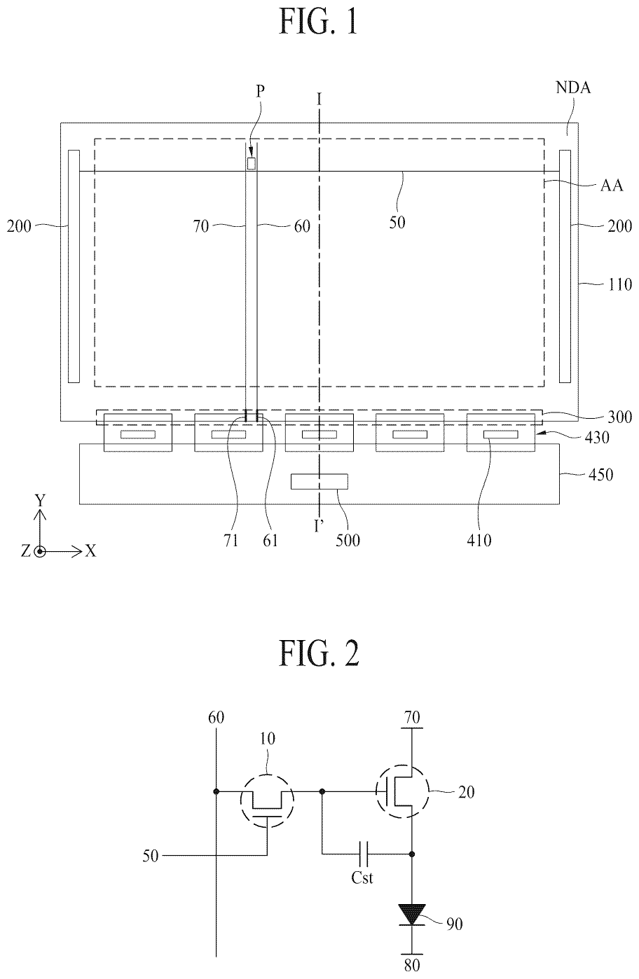

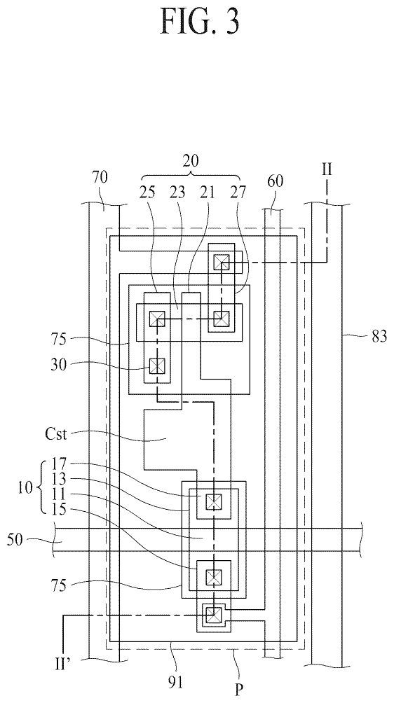

Hereinafter, referring to FIG. 2 to FIG. 4, a light emitting display device according to an embodiment of the present disclosure will be explained. Firstly, referring to FIG. 2 and FIG. 3, a light emitting display device on a top view according to an embodiment of the present disclosure. FIG. 2 is an equivalent circuit diagram illustrating a structure of one pixel included in the light emitting display according to FIG. 1. FIG. 3 is an enlarged plane view illustrating the structure of one pixel in the light emitting display device according to FIGS. 1.

The light emitting display device according to an embodiment of the present disclosure may comprise a display layer 600 formed on a substrate 110. The light emitting display device according to an embodiment of the present disclosure may comprise a display layer 600 formed on a substrate 110. The display layer 600 may include a display area AA and a non-display area NDA. The display area AA may include a plurality of pixels P arrayed in a matrix manner.

Each pixel P of the light emitting display device according to an embodiment may be defined by a scan line 50, a data line 60 and a driving current line 70. Within each pixel P, a switching thin film transistor 10, a driving thin film transistor 20, a light emitting diode 90, and a storage capacitor Cst (or capacitance) may be disposed. The driving current line 70 is supplied with a high-potential voltage for driving the light emitting diode 90.

The switching thin film transistor 10 may be configured to connected to the scan line 50 and the data line 60. The switching thin film transistor 10 may include a gate electrode 11, a semiconductor layer 13, a source electrode 15 and a drain electrode 17. The gate electrode 11 may be a portion of the scan line 50. The semiconductor layer 13 may overlap with the gate electrode 11. For example, the semiconductor layer 13 may be disposed as crossing the scan line 50. The overlapped portion of the semiconductor layer 13 with the gate electrode 11 may be defined as a channel region. The source electrode 15 is branched from or connected to the data line 60, and the drain electrode 17 is connected to the driving thin film transistor 20. By supplying the data signal to the driving thin film transistor 20, the switching thin film transistor 10 may play role of selecting a pixel to operate.

The driving thin film transistor 20 may play role of driving the light emitting diode 90 included into a pixel P selected by the switching thin film transistor 10. The driving thin film transistor 20 includes a gate electrode 21, a semiconductor layer 23, a source electrode 25 and a drain electrode 27. The gate electrode 21 of the driving thin film transistor 20 may be connected to or extended from the drain electrode 17 of the switching thin film transistor 10. The semiconductor layer 23 may be disposed as crossing the gate electrode 21. The overlapped portion of the semiconductor layer 23 with the gate electrode 21 may be defined as a channel region. The drain electrode 27 of the driving thin film transistor 20 is branched from or connected to the driving current line 70, and the source electrode 25 is connected to an anode electrode 91 of the light emitting diode 91 (or light emitting element). The storage capacitor Cst may be disposed between the gate electrode 21 of the driving thin film transistor 20 and the anode electrode 91 of the light emitting diode 90.

The driving thin film transistor 20 is disposed between the driving current line 70 and the light emitting diode 90. The driving thin film transistor 20 controls the amount of the electric current flowing from the driving current line 70 to the light emitting diode 90 according to the voltage difference between the gate electrode 21 and the source electrode 25.

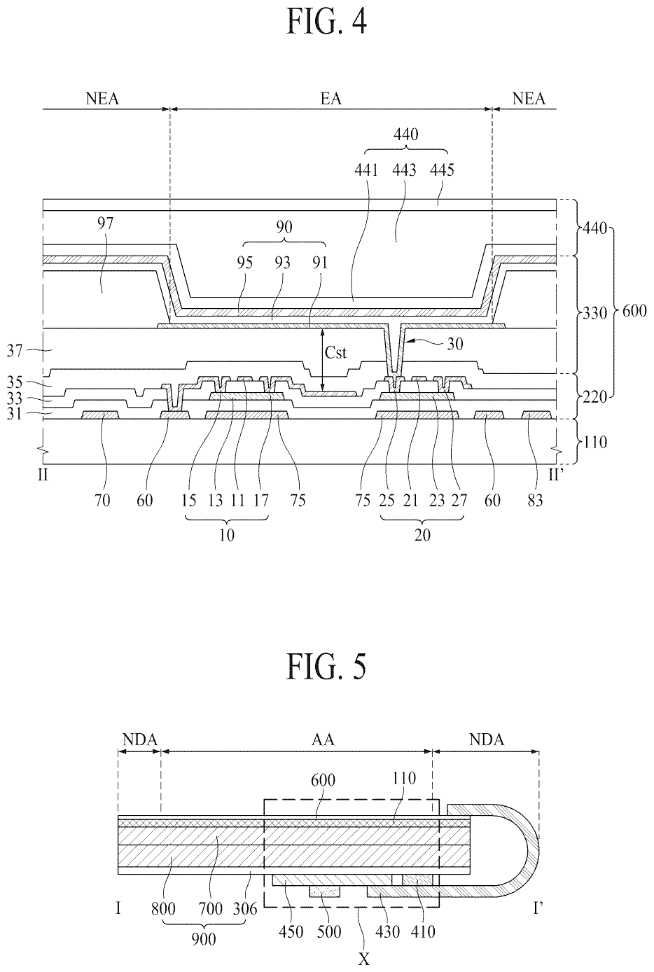

Further referring to FIG. 4, a cross-sectional structure of the light emitting display device according to the present disclosure will be described. FIG. 4 is a cross-sectional view, cutting along line II-II′ in FIG. 3, illustrating a structure of a light emitting display device according to an embodiment of the present disclosure. The display device according to and embodiment of the present disclosure includes a display layer 600 formed on a substrate 110. The display layer 600 may include a driving element layer 220, a light emitting element layer 330 and an encapsulation layer 440. The driving element layer 220 may include a plurality of thin layers formed on the substrate 110. The driving element layer 220 may include a switching thin film transistor 10, a driving thin film transistor 20 and a storage capacitor Cst.

In detail, a data line 60, a driving current line 70, an auxiliary line 83 and a light shielding layer 75 are formed on the substrate 110. The light shielding layer 75 may have an island shape which is separated from the data line 60 and the driving current line 70 and the light shielding layer 75, and overlapped with the semiconductor layers 13 and 23. In some cased, the light shielding layer 75 may be omitted.

A buffer layer 31 is deposited on the substrate 110 as covering the driving current line 70, the auxiliary line 83, the data line 60 and the light shielding layer 75. The semiconductor layer 13 of the switching thin film transistor 10 and the semiconductor layer 23 of the driving thin film transistor 20 are formed on the buffer layer 31. At least the channel regions of the semiconductor layers 13 and 23 are preferably disposed as overlapped with the light shielding layer 75.

A gate insulating layer 33 is deposited on the substrate 110 having the semiconductor layers 13 and 23. A gate electrode 11 overlapping the semiconductor layer 13 of the switching thin film transistor 10, and a gate electrode 21 overlapping the semiconductor layer 23 of the driving thin film transistor 20 are formed on the gate insulating layer 33. In addition, at both sides of the gate electrode 11 of the switching thin film transistor 10, a source electrode 15 contacting to one side of the semiconductor 13 and being apart from the gate electrode 11, and a drain electrode 17 contacting to the other side of the semiconductor 13 and being apart from the gate electrode 11 are formed. Likewise, at both sides of the gate electrode 21 of the driving thin film transistor 20, a source electrode 25 contacting to one side of the semiconductor 23 and being apart from the gate electrode 21, and a drain electrode 27 contacting to the other side of the semiconductor 23 and being apart from the gate electrode 21 are formed.

Even though the gate electrodes 11 and 21 and the source-drain electrodes 15, 17, 25, 27 are formed on the same layer, they are separated from each other spatially and electrically. In addition, the source electrode 15 of the switching thin film transistor 10 is connected to the data line 60 via a contact hole penetrating the gate insulating layer 33 and the buffer layer 31. Even though it is not shown in figures, the drain electrode 27 of the driving thin film transistor 20 is connected to the driving current line 70 via a contact hole penetrating the gate insulating layer 33.

A passivation layer 35 is deposited on the substrate 110 having the thin film transistors 10 and 20. The passivation layer 35 is preferably made of an inorganic material such as silicon oxide (SiOx) or silicon nitride (SiNx).

The light emitting element layer 330 is formed on the driving element layer 220. The light emitting element layer 330 is includes a light emitting diode 90. Before forming the light emitting diode 90, a planarization layer 37 is deposited on the passivation layer 35. The surface of the substrate 110 on which the thin film transistors 10 and 20 are formed is not uniform or even, so the planarization layer 37 is a thin film layer for flattening the uneven surface condition. In order that make the height difference caused by uneven surface conditions are not reflected and have the even height overall the surface, the planarization layer 37 may be formed of an organic material. A pixel contact hole 30 exposing a part of the source electrode 25 of the driving thin film transistor 20 is formed in the passivation layer 35 and the planarization layer 37.

The light emitting diode 90 includes an anode electrode 91, an emission layer 93 and a cathode electrode 95. The light emitting diode 90 generates light according to the current controlled by the driving thin film transistor 20. In other words, the light emitting diode 90 displays an image by emitting light according to an electric current controlled by the driving thin film transistor 20. The anode electrode 91 of the light emitting diode 90 is connected to the source electrode 25 of the driving thin film transistor 20, and the cathode electrode 95 is connected to the low-potential line 80 to which a low-potential voltage is supplied. The light emitting diode 90 is driven by the electrical current flowing from the driving current line 70 to the low-potential line 80 by the driving thin film transistor 20.

The anode electrode 91 is formed on the upper surface of the planarization layer 37. The anode electrode 91 is connected to the source electrode 25 of the driving thin film transistor 20 via the pixel contact hole 30. The anode electrode 91 has different structure depending on the emission type of the light emitting diode 90. For example, in the case of the bottom emission type that provides light in the direction in which the substrate 110 is placed, the anode electrode 91 may be formed of a transparent conductive material. For another example, in the case of the top emission type that provide light in the upper direction opposite to the substrate 110, the anode electrode 91 may be made of a metal material with excellent light reflectance. Since the present disclosure relates to a top emission type display device, the anode electrode 91 preferably may be made of a metal material with thickness of 1,000Å or more.

A bank 97 is formed on the substate 110 having the anode electrode 91. In one embodiment, the bank 97 is made of an insulating material such as inorganic insulating material or organic insulating material. Here, the bank 97 is made of an organic insulating material. The bank 97 covers circumferential areas of the anode electrode 91, and exposes middle portions of the anode electrode 91. The exposed portions of the anode electrode 91 is defined as an emission area EA, and the covered portions of the anode electrode 91 by the bank 97 is defined as a non-emission area EA.

The emission layer 93 is deposited on the anode electrode 91 and the bank 97. The emission layer 93 may be stacked on the entire display area AA of the substrate 110 to cover the anode electrode 91 and the bank 97. For an example, the emission layer 93 may include at least two emission parts for generating white light. In detail, the emission layer 93 may include a first emission part and a second emission part vertically stacked for generating white light by mixing the first light from the first emission part and the second light from the second emission part.

For another example, the emission layer 93 may include any one of a blue emission part, a green emission part, and a red emission part for generating light corresponding to a color set in each pixel. Further, the light emitting diode 90 may include a functional layer for improving light emitting efficiency and/or lifetime of the emission layer 93.

A cathode electrode 95 is deposited on the entire surface of the substrate 110 on which the emission layer 93 is formed. The cathode electrode 95 is deposited to make surface contact with the emission layer 93. The cathode electrode 95 is formed over the entire substrate 110 to be commonly connected to the emission layer 93 deposited in all pixels. In the case of the top emission type, the cathode electrode 95 may include a transparent conductive material. For example, the cathode electrode 95 may be made of a transparent conductive material such as indium-tin-oxide (ITO) or indium-zinc-oxide (IZO).

An encapsulation layer 440 may be disposed on the light emitting element layer 330. For example, the encapsulation layer 440 may include a first inorganic layer 441, an organic layer 443 and a second inorganic layer 445 which are sequentially stacked. For another example, the encapsulation layer 40 may include single inorganic layer or multiple organic layers.

Hereinafter, further referring to FIG. 5, a structure in which a driving element is disposed on the back of the substrate 110 in a light emitting display device according to an example of the present disclosure will be explained. FIG. 5 is a side view along cutting line I-I′ in FIG. 1, for illustrating a structure of the light emitting display device according to an embodiment of the present disclosure. FIG. 1 shows a planar structure in which the flexible circuit film 430 is unfolded, but FIG. 5 shows a cross-sectional structure in which the flexible circuit film 430 is bent and the driving elements are arranged on the backside of the substrate 110.

The display layer 600 may be disposed on the upper surface of the substrate 110. The display layer 600 may include a display area AA and a non-display area NDA. The display area AA may include a plurality of pixels P. The non-display area NDA may include a gate driver 200 and a pad portion 300.

A heat insulating layer 700 may be attached to the lower surface (or rear surface or backside surface) of the substrate 110 to protect the substrate 110. A heat dissipation layer 800 may be attached to the lower surface of the heat insulating layer 700. An adhesive layer 306 may be attached and/or applied to the lower surface of the heat dissipation layer 800. A source driving IC 410 and a circuit board 450 may be attached lower surface of the adhesive layer 306. By bending the flexible circuit film 430 on which the source driving IC 410 is mounted and the circuit board 450 is connected, the source driving IC 410 and the circuit board 450 may be attached to the adhesive layer 306 disposed on the rear surface of the substrate 110.

The light emitting display device according to an embodiment of the present disclosure may have a display layer 600 at a front side of the substrate 110 and a driving element including the source driving IC 410 and the circuit board 450 at a rear side of the substrate 110, as shown in FIG. 5. The display elements disposed in the display layer 600 may generate heats, and the driving elements disposed under the substrate 110 may generate heats.

Under this condition, when the heat generated by the light emitting elements and the heat generated by the driving elements may be concentrated in the display layer 600, the light emitting diode 90 described in FIG. 4 configuring the display layer 600 and then a problem may occur that deteriorates the display elements and ultimately shortens the lifespan of the display device. To solve this problem, a structure is needed that may quickly dissipate heat generated from the display device so that the heat does not affect the display element. In addition, a heat insulating structure may be needed to prevent heat generated from the display layer 600 from affecting the driving element 410 and 500, and to prevent heat generated from the driving elements 410 and 500 from affecting the display layer 600.

The light emitting display device according to the present disclosure as shown in FIG. 5 may include a heat insulating layer 700 and a heat dissipation layer 800 disposed between the substrate 110 and the driving elements 410 and 500. The heat insulating layer 700 may function to block heat transfer in the vertical direction to prevent the heat generated by the display layer 600 from affecting the driving elements 410 and 500, and to prevent the heat generated by the driving elements 410 and 500 from affecting the display layer 600. The heat dissipation layer 800 may be an element that diffuse heat generated from the driving elements 410 and 500 in the horizontal direction of the substrate 110 and quickly discharges it to the outside.

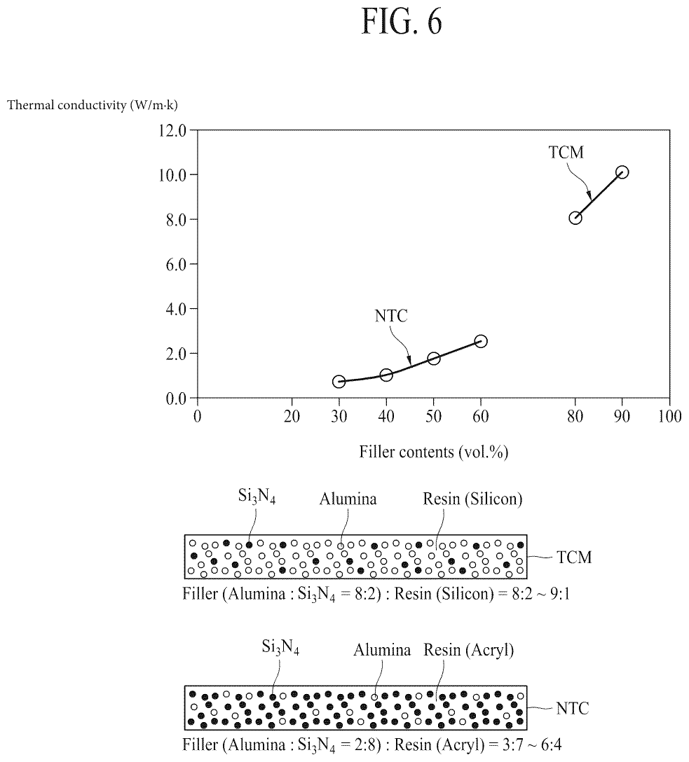

Hereinafter, referring to FIGS. 6 to 13, the structural features for heat insulation and heat dissipation in the light emitting display device according to the present disclosure will be described in detail.

Firstly, referring to FIG. 6, the structure and properties of non-thermal conductive materials and thermal conductive materials applied to the heat insulation structure and the heat dissipation structure of the present disclosure will be described. FIG. 6 is a diagram illustrating a structure of a non-thermally conductive material and a thermally conductive material according to an embodiment of the present disclosure, and the thermal conductivity of each of these materials.

As shown in FIG. 6, the thermal conductive material TCM may be implemented in the form of thin film or thin layer. For example, the thermal conductive material TCM may be formed in the form of a thin film by mixing filler with a silicon-based resin material and then curing them. For another example, the thermal conductive material TCM may be formed into an adhesive layer by adding an adhesive element to a silicon-based resin material.

The thermal conductive material TCM may preferably have a thermal conductivity in range of 8 W/m·k to 11 W/m·k. In order to ensure such thermal conductivity, the thermal conductive material TCM may be formed by mixing a filler with high thermal conductivity into silicon resin. For example, the volume content ratio (vol %) of the filler and silicon resin may preferably be in range of 8:2 to 9:1. Here, the filler may be a mixture of alumina (or aluminum oxide) powder and silicon nitride (Si3N4) powder, and the volume content ratio may preferably be Alumina: Si3N4=8:2. That is, the thermal conductive material TCM may include a filler and a silicon-based resin with a volume content ratio in range of 8:2 to 9:1. The filler may includes alumina particles and silicon nitride particles with a volume content ratio of 8:2. Here, the alumina particles may include aluminum particles and/or aluminum oxide particles.

As shown in FIG. 6, the non-thermal conductive material NTC may also be implemented in thin film form. For an example, the non-thermal conductive material NTC may be formed in the form of a thin film by mixing a filler with an acryl-based resin material and then curing them. For another example, the non-thermal conductive material NTC may be formed into an adhesive layer by adding an adhesive element to an acryl-based resin material.

The non-thermal conductive material NTC may preferably have a thermal conductivity in range of 1 W/m·k to 3 W/m·k. In order to ensure such thermal conductivity, the non-thermal conductive material NTC may be formed by mixing a filler with low thermal conductivity into acryl resin. For example, the volume content ratio (vol %) of the filler and acryl resin may preferably be in range of 3:7 to 6:4. Here, the filler may be a mixture of alumina powder and silicon nitride (Si3N4) powder, and the volume content ratio may preferably be Alumina: Si3N4=2:8. That is, the non-thermal conductive material NTC may include a filler and an acryl-based resin with a volume content ratio in range of 3:7 to 6:4. The filler may include alumina particles and silicon nitride particles with a volume content ratio of 2:8.

Here, the names of ‘high thermal conductivity’ and ‘low thermal conductivity’ are terms used to configure the two materials used in the present disclosure, that is, one layer with relatively high thermal conductivity and the other layer with relatively low thermal conductivity. The thermal conductivity of the heat transfer material and the heat blocking material used in the present disclosure is set with reference to the heat generated form the light emitting display device and the heat allowable in the product. Therefore, ‘high thermal conductivity’ means a thermal conductivity of 8 W/m·k to 11 W/m·k, and ‘low thermal conductivity’ means a thermal conductivity of 1 W/m·k to 3 W/m·k.

Hereinafter, various embodiments of the present disclosure will be explained in which the non-thermal conductive material and/or the thermal conductive material described in FIG. 6 may be applied to a light emitting display device in various ways and structures.

### First Embodiment

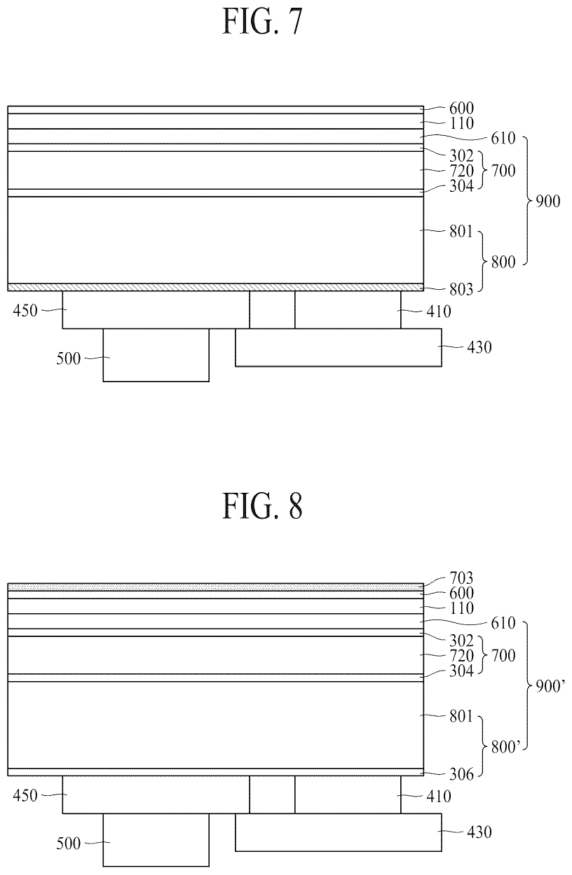

Referring to FIG. 7, a light emitting display device according to a first embodiment of the present disclosure will be explained. FIG. 7 is an enlarged cross-sectional view of square dotted area ‘X’ in FIG. 5, illustrating a structure of the light emitting display device according to a first embodiment of the present disclosure.

Referring to FIG. 7, the light emitting display device according to the first embodiment of the present disclosure may comprise a substrate 110, a display layer 600 and a underneath structure 900. The underneath structure 900 may include a protective layer 610, a heat insulating layer 700 and a heat dissipation layer 800. In addition, driving elements may be disposed under the heat dissipation layer 800. The driving elements may include a source driving IC 410, a circuit board 450 and a timing controller 500.

In detail, the display layer 600 may be formed on the upper surface of the substrate 110. The display layer 600 may have a cross-sectional structure explained with FIG. 5. For example, the display layer 600 may include a driving element layer 220, a light emitting element layer 330 and an encapsulation layer 440.

The protective layer 610 may be stacked on the lower surface (or rear surface or bottom surface) of the substrate 110. As the protective layer 610 may be an element for protecting the substrate 110 from cracking or breaking, the protective layer 610 may be made of an organic material. The protective layer 610 may be formed by depositing an organic material on the lower surface of the substrate 110 using a deposition process, or by attaching a film made of an organic material to the lower surface of the substrate 110.

The heat insulating layer 700 may be attached on the lower surface of the protective layer 610. For example, the heat insulating layer 700 may have a structure in which a first adhesive layer 302, a shock absorbing layer 720 and a second adhesive layer 304 are sequentially stacked. The heat insulating layer 700 may be made in the form of a film in which the first adhesive layer 302 and the second adhesive layer 304 are applied to the top surface and the bottom surface of the shock absorbing layer 720, respectively. The heat insulating layer 700 may be disposed so that one surface of the first adhesive layer 302 is attached to the bottom surface of the protective layer 610. Further, the heat insulating layer 700 may have a same size as the protective layer 610. The bottom surface of the first adhesive layer 301 may be attached on the entire top surface of the heat insulating layer 700. The top surface of the first adhesive layer 301 may be attached on the entire bottom surface of the protective layer 610. The first adhesive layer 302 and the second adhesive layer 304 may include a pressure sensitive adhesive material.

In one embodiment, the shock absorbing layer 720 may be made of a material that protects the substrate 110 and the display layer 600 by absorbing physical shock from the outside. In addition, the shock absorbing layer 720 may have a low thermal conductivity for preventing the heat generated from the under outside of the shock absorbing layer 720 from being transferred to the top direction, and may be made of a material that prevents the heat generated from the top outside of the shock absorbing layer 720 from being transferred to the bottom direction. For example, the shock absorbing layer 720 may be made of polyurethane, which has a very low thermal conductivity and an excellent physical shock absorption property.

The heat dissipation layer 800 may be disposed at the bottom surface of the heat insulating layer 700. The heat dissipation layer 800 may be attached on one surface of the second adhesive layer 304 which is attached on bottom surface of the heat insulating layer 700. The heat dissipation layer 800 may have a same size as the heat insulating layer 700, and may be attached on one entire surface of the second adhesive layer 302 which is attached on the entire bottom surface of the heat insulating layer 700. The heat dissipation layer 800 may have a structure in which a metal layer 801 and a thermal conductive adhesive layer 803 are stacked. For an example, the metal layer 801 may be a plate-shaped metal material with a certain thickness. For another example, the metal layer 801 may be made of a metal material having a thin film shape. In particular, the metal layer 801 may be preferably formed of a metal material such as aluminum, which has excellent thermal conductivity in the horizontal surface direction (or planar surface direction). The thermal conductivity adhesive layer 803 may be preferably an adhesive layer made of the thermal conductive material TCM described in FIG. 6. For an example, the thermal conductive adhesive layer 803 may be made of a material including a filler and a silicon-based adhesive resin with the volume contents of 8:2 to 9:1. The filler may be made by mixing alumina (or aluminium oxide) particles (or powder) and silicon nitride particles (or powder) with a volume content of 8:2.

The driving elements may be attached on the bottom surface of the thermal conductivity adhesive layer 803. The driving elements may be attached one portion of the bottom surface of the thermal conductivity adhesive layer 803. For example, the source driving IC 410 and the circuit board 450 may be attached to the thermal conductivity adhesive layer 803. The timing controller 500 may be mounted on the bottom surface of the circuit board 450.

With this structure, the heat generated from the driving elements may be transferred to the metal layer 801 through the thermal conductivity adhesive layer 803, and diffused to the horizontal surface direction of the metal layer 801 and then discharged outside. In particular, the thermal conductivity adhesive layer 803 may have a much higher thermal conductivity than the first adhesive layer 302 and the second adhesive layer 304 made of a pressure-sensitive adhesive material, so the thermal conductivity adhesive layer 803 may quickly transfer the heat generated from the driving elements to the metal layer 801.

Meanwhile, the heat generated from the driving elements may be prevented from being transferred to the display layer 600 by the heat insulating layer 700. In addition, the heat generated from the display layer 600 may also be prevented from being transferred to the driving elements by the heat insulating layer 700.

According the first embodiment, the thermal conductive adhesive layer 803 disposed under the metal layer 801 may transfer the heat generated from the driving elements to the metal layer 801 very quickly. Therefore, the heat generated from the driving elements may be quickly discharged to the outside.

### Second Embodiment

Referring to FIG. 8, a light emitting display device according to a second embodiment of the present disclosure will be explained. FIG. 8 is an enlarged cross-sectional view of square dotted area ‘X’ in FIG. 5, illustrating a structure of the light emitting display device according to a second embodiment of the present disclosure.

Referring to FIG. 8, the light emitting display device according to the second embodiment of the present disclosure may comprise a substrate 110, a display layer 600 and an underneath structure 900′. The underneath structure 900′ may include a protective layer 610, a heat insulating layer 700 and a heat dissipation layer 800′. A thermal conducting cover layer 703 may be disposed on the display layer 600. Further, the driving elements may be disposed under the heat dissipation layer 800′. The driving elements may include a source driving IC 410, a circuit board 450 and a timing controller 500.

The display layer 600 may be formed on the top surface of the substrate 100. The display layer 600 may have a cross-sectional structure explained with FIG. 5. For example, the display layer 600 may include a driving element layer 220, a light emitting element layer 330 and an encapsulation layer 440.

The thermal conducting cover layer 703 may be formed on the top surface of the substrate 110. The thermal conducting cover layer 703 may be stacked to have an area equal to or slightly larger than the display area AA so as to completely cover the display area AA in the display layer 600. For example, even though it is not shown in figures, the thermal conducting cover layer 703 may be not formed on the pad portion 300 of the display layer 600 to which the flexible circuit film 430 is attached.

The thermal conducting cover layer 703 may be preferably formed by applying an organic material, curing it and attaching it to the top surface of the display layer 600 in the form of a film. The thermal conducting cover layer 703 may be a film-type thermal conductive material (TCM) described with FIG. 6. For an example, the thermal conductive adhesive layer 803 may be made of a material including a filler and a silicon-based resin with the volume contents of 8:2 to 9:1. The filler may be made by mixing alumina particles (or powder) and silicon nitride particles (or powder) with a volume content of 8:2. After applying this material, the film type thermal conducting cover layer 703 may be formed by curing.

The protective layer 610 may be stacked on the bottom surface of the substrate 110. The protective layer 610 may be used to protect the substrate 110 from cracking or breaking, and may be made of an organic material. The protective layer 610 may be attached to cover the entire bottom surface of the substrate 110.

The heat insulating layer 700 may be attached on the lower surface of the protective layer 610. For example, the heat insulating layer 700 may have a structure in which a first adhesive layer 302, a shock absorbing layer 720, and a second adhesive layer 304 are sequentially stacked. The heat insulating layer 700 may be made in the form of a film in which the first adhesive layer 302 and the second adhesive layer 304 are applied to the top surface and the bottom surface of the shock absorbing layer 720, respectively. The heat insulating layer 700 may be disposed so that one surface of the first adhesive layer 302 is attached to the bottom surface of the protective layer 610. Further, the heat insulating layer 700 may have a same size as the protective layer 610. The bottom surface of the first adhesive layer 301 may be attached on the entire top surface of the heat insulating layer 700. The top surface of the first adhesive layer 302 may be attached on the entire bottom surface of the protective layer 610. The first adhesive layer 302 and the second adhesive layer 304 may include a pressure sensitive adhesive material.

The shock absorbing layer 720 may be made of a material that protects the substrate 110 and the display layer 600 by absorbing physical shock from the outside. In addition, the shock absorbing layer 720 may have a low thermal conductivity for preventing the heat generated from the under outside of the shock absorbing layer 720 from being transferred to the top direction, and may be preferably made of a material that prevents the heat generated from the top outside of the shock absorbing layer 720 from being transferred to the bottom direction. For example, the shock absorbing layer 720 may be made of polyurethane, which has a very low thermal conductivity and an excellent physical shock absorption property.

The heat dissipation layer 800′ may be disposed at the bottom surface of the heat insulating layer 700. The heat dissipation layer 800′ may be attached on one surface of the second adhesive layer 304 which is attached on bottom surface of the heat insulating layer 700. The heat dissipation layer 800′ may have a same size as the heat insulating layer 700, and may be attached on one entire surface of the second adhesive layer 302 which is attached on the entire bottom surface of the heat insulating layer 700. The heat dissipation layer 800′ may have a structure in which a metal layer 801 and a third adhesive layer 306 are stacked. For an example, the metal layer 801 may be a plate-shaped metal material with a certain thickness. For another example, the metal layer 801 may be made of a metal material having a thin film shape. In particular, the metal layer 801 may be preferably formed of a metal material such as aluminum, which has excellent thermal conductivity in the horizontal surface direction (or planar surface direction). The third adhesive layer 306 may be made of the same pressure-sensitive adhesive material as the first adhesive layer 302 and the second adhesive layer 304.

The driving elements may be attached on the bottom surface of the third adhesive layer 306. The driving elements may be attached one portion of the bottom surface of the third adhesive layer 306. For example, the source driving IC 410 and the circuit board 450 may be attached to the third adhesive layer 306. The timing controller 500 may be mounted on the bottom surface of the circuit board 450.

With this structure, the heat generated from the driving elements may be transferred to the metal layer 801, and diffused to the horizontal surface direction of the metal layer 801 and then discharged outside. Meanwhile, the heat generated from the driving elements may be prevented from being transferred to the display layer 600 by the heat insulating layer 700. In addition, the heat generated from the display layer 600 may be quickly discharged out of the top surface through the thermal conductive cover layer 703 applied to the top surface. Although some of heat may be transferred toward the substrate 110, the heat insulating layer 700 may prevent the heat from being transferred to the driving elements.

According to the second embodiment, the thermal conductive cover layer 703 stacked on the display layer 600 may discharge the heat to the outside very quickly. Some of the heat may be transmitted toward the substrate 110, but compared to the case where the thermal conductive cover layer 703 is not present, the heat transmitted toward the substrate 110 may be minimized or eliminated.

### Third Embodiment

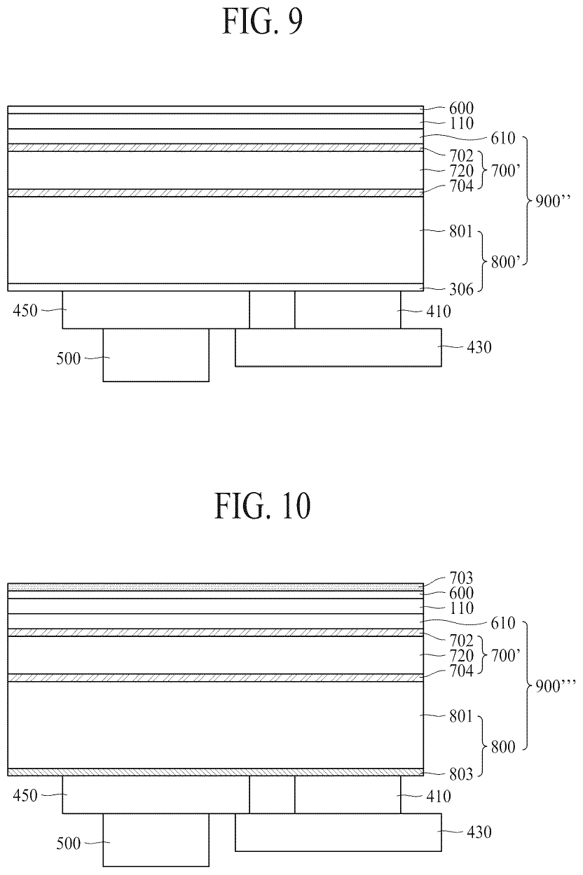

Referring to FIG. 9, a light emitting display device according to a third embodiment of the present disclosure will be explained. FIG. 9 is an enlarged cross-sectional view of square dotted area ‘X’ in FIG. 5, illustrating a structure of the light emitting display device according to a third embodiment of the present disclosure.

Referring to FIG. 9, the light emitting display device according to the third embodiment of the present disclosure may comprise a substrate 110, a display layer 600 and an underneath structure 900″. The underneath structure 900″ may include a protective layer 610, a heat insulating layer 700′ and a heat dissipation layer 800′. Further, the driving elements may be disposed under the heat dissipation layer 800′. The driving elements may include a source driving IC 410, a circuit board 450 and a timing controller 500.

The display layer 600 may be formed on the top surface of the substrate 110. The display layer 600 may have a structure described in FIG. 5. For an example, the display layer 600 may include a driving element layer 220, a light emitting element layer 330 and an encapsulation layer 440.

The protective layer 610 may be attached on the bottom surface of the substrate 110. As the protective layer 610 may be an element for protecting the substrate 110 from being broken or cracked, the protective layer 610 may be made of an organic material.

The heat insulating layer 700′ may be attached on thee bottom surface of the protective layer 610. For an example, the heat insulating layer 700′ may have a structure in which a first non-thermal conductive adhesive 702, a shock absorbing layer 720 and a second non-thermal conductive adhesive layer 704 are sequentially stacked. The heat insulating layer 700′ may be made in the form of a film in which the first non-thermal conductive adhesive 702 and the second non-thermal conductive adhesive 704 are applied to the top surface and the bottom surface of the shock absorbing layer 720, respectively. The heat insulating layer 700′ may be disposed so that one surface of the first non-thermal conductive adhesive 702 is attached to the bottom surface of the protective layer 610. Further, the heat insulating layer 700′ may have a same size as the protective layer 610. The bottom surface of the first non-thermal conductive adhesive 702 may be attached on the entire top surface of the heat insulating layer 700′. The top surface of the first non-thermal conductive adhesive 702 may be attached on the entire bottom surface of the protective layer 610.

The shock absorbing layer 720 may be made of a material that protects the substrate 110 and the display layer 600 by absorbing physical shock from the outside. In addition, the shock absorbing layer 720 may have a low thermal conductivity for preventing the heat generated from the under outside of the shock absorbing layer 720 from being transferred to the top direction, and may be made of a material that prevents the heat generated from the top outside of the shock absorbing layer 720 from being transferred to the bottom direction. For example, the shock absorbing layer 720 may be made of polyurethane, which has a very low thermal conductivity and an excellent physical shock absorption property.

The first non-thermal conductive adhesive 702 and the second non-thermal conductive adhesive 704 may be preferably made of a non-thermal conductive material NTC described with FIG. 6. For an example, the first non-thermal conductive adhesive 702 and the second non-thermal conductive adhesive 704 may be made of a material including a filler and an acryl-based adhesive resin with the volume contents of 8:2 to 9:1. The filler may be made by mixing alumina particles (or powder) and silicon nitride particles (or powder) with a volume content of 2:8. The shock absorbing layer 720 may have a function of preventing heat from transferring in the vertical direction. In order to effectively prevent the heat accumulated, as the light emitting display device is used for a long time, from being transferred in the vertical direction, it is preferable to further include the first non-thermal conductive adhesive layer 702 and the second non-thermal conductive adhesive layer 704.

The heat dissipation layer 800′ may be attached on the bottom surface of the heat insulating layer 700′. The heat dissipation layer 800′ may be attached on one surface of the second non-thermal conductive adhesive layer 704 attached to the heat insulating layer 700′. In addition, the dissipation layer 800′ may have the same size as the heat insulating layer 700′, and may be attached on one entire surface of the second non-thermal conductive adhesive layer 704 attached on the entire bottom surface of the heat insulating layer 700′. The heat dissipation layer 800′ may have a structure in which a metal layer 801 and a third adhesive layer 306 are stacked. For an example, the metal layer 801 may be a plate-shaped metal material with a certain thickness. For another example, the metal layer 801 may be made of a metal material having a thin film shape. In particular, the metal layer 801 may be preferably formed of a metal material such as aluminum, which has excellent thermal conductivity in the horizontal surface direction (or planar surface direction). The third adhesive layer 306 may be made of the pressure-sensitive adhesive material.

The driving elements may be attached on the bottom surface of the third adhesive layer 306. The driving elements may be attached one portion of the bottom surface of the third adhesive layer 306. For example, the source driving IC 410 and the circuit board 450 may be attached to the third adhesive layer 306. The timing controller 500 may be mounted on the bottom surface of the circuit board 450.

With this structure, the heat generated from the driving elements may be transferred to the metal layer 801, and diffused to the horizontal surface direction of the metal layer 801 and then discharged outside. Meanwhile, the heat generated from the driving elements may be prevented from being transferred to the display layer 600 by the heat insulating layer 700′. In addition, the heat generated from the display layer 600 may be prevented from transferring to the driving elements by the heat insulating layer 700′. According to the third embodiment, heat insulation performance may be improved so that the heat generated from the display layer 600 and the heat generated from the driving elements may not pass through the substrate 110 and affect each other.

### Fourth Embodiment

Referring to FIG. 10, a light emitting display device according to a fourth embodiment of the present disclosure will be explained. FIG. 10 is an enlarged cross-sectional view of square dotted area ‘X’ in FIG. 5, illustrating a structure of the light emitting display device according to a fourth embodiment of the present disclosure.

Referring to FIG. 10, the light emitting display device according to the fourth embodiment of the present disclosure may comprise a substrate 110, a display layer 600 and an underneath structure 900″′. The underneath structure 900″′ may include a protective layer 610, a heat insulating layer 700′ and a heat dissipation layer 800. A thermal conductive cover layer 703 may be disposed on the display layer 600. In addition, the driving elements may be disposed under the heat dissipation layer 800. For an example, the driving elements may include a source driving IC 410, a circuit board 450 and a timing controller 500.

The display layer 600 may be formed on the top surface of the substrate 110. The display layer 600 may have a cross-sectional structure described with FIG. 5. For an example, the display layer 600 may include a driving element layer 220, a light emitting element layer 330 and an encapsulation layer 440.

The thermal conducting cover layer 703 may be formed on the top surface of the substrate 110. The thermal conducting cover layer 703 may be stacked to have an area equal to or slightly larger than the display area AA so as to completely cover the display area AA in the display layer 600. For example, even though it is not shown in figures, the thermal conducting cover layer 703 may be not formed on the pad portion 300 of the display layer 600 to which the flexible circuit film 430 is attached.

The thermal conducting cover layer 703 may be formed by applying an organic material, curing it and attaching it to the top surface of the display layer 600 in the form of a film. The thermal conducting cover layer 703 may be a film-type thermal conductive material (TCM) described with FIG. 6. For an example, the thermal conductive adhesive layer 803 may be made of a material including a filler and a silicon-based resin with the volume contents of 8:2 to 9:1. The filler may be made by mixing alumina particles (or powder) and silicon nitride particles (or powder) with a volume content of 8:2. After applying this material, the film type thermal conducting cover layer 703 may be formed by curing.

The protective layer 610 may be deposited on the bottom surface of the substrate 110. The protective layer 610 may be used to protect the substrate 110 from cracking or breaking, and may be made of an organic material. As the protective layer 610 is deposited to the substrate 110. The thickness of the substrate 110 having the protective layer 610 may have minimized thickness.

The heat insulating layer 700′ may be attached on the bottom surface of the protective layer 610. For an example, the heat insulating layer 700′ may have a structure in which a first non-thermal conductive adhesive 702, a shock absorbing layer 720 and a second non-thermal conductive adhesive layer 704 are sequentially stacked. The heat insulating layer 700′ may be made in the form of a film in which the first non-thermal conductive adhesive 702 and the second non-thermal conductive adhesive 704 are applied to the top surface and the bottom surface of the shock absorbing layer 720, respectively. The heat insulating layer 700′ may be disposed so that one surface of the first non-thermal conductive adhesive 702 is attached to the bottom surface of the protective layer 610. Further, the heat insulating layer 700′ may have a same size as the protective layer 610. The bottom surface of the first non-thermal conductive adhesive 702 may be attached on the entire top surface of the heat insulating layer 700′. The top surface of the first non-thermal conductive adhesive 702 may be attached on the entire bottom surface of the protective layer 610.

The shock absorbing layer 720 may be made of a material that protects the substrate 110 and the display layer 600 by absorbing physical shock from the outside. In addition, the shock absorbing layer 720 may have a low thermal conductivity for preventing the heat generated from the under outside of the shock absorbing layer 720 from being transferred to the top direction, and may be made of a material that prevents the heat generated from the top outside of the shock absorbing layer 720 from being transferred to the bottom direction. For example, the shock absorbing layer 720 may be made of polyurethane, which has a very low thermal conductivity and an excellent physical shock absorption property.

The first non-thermal conductive adhesive 702 and the second non-thermal conductive adhesive 704 may be made of a non-thermal conductive material NTC described with FIG. 6. For an example, the first non-thermal conductive adhesive 702 and the second non-thermal conductive adhesive 704 may be made of a material including a filler and an acryl-based adhesive resin with the volume contents of 3:7 to 6:4. The filler may be made by mixing alumina particles (or powder) and silicon nitride particles (or powder) with a volume content of 2:8. The shock absorbing layer 720 may have a function of preventing heat from transferring in the vertical direction. In order to effectively prevent the heat accumulated, as the light emitting display device is used for a long time, from being transferred in the vertical direction, it is preferable to further include the first non-thermal conductive adhesive layer 702 and the second non-thermal conductive adhesive layer 704.

The heat dissipation layer 800 may be attached on the bottom surface of the heat insulating layer 700′. The heat dissipation layer 800 may be attached on one surface of the second non-thermal conductive adhesive layer 704 attached to the heat insulating layer 700′. In addition, the dissipation layer 800 may have the same size as the heat insulating layer 700′, and may be attached on one entire surface of the second non-thermal conductive adhesive layer 704 attached on the entire bottom surface of the heat insulating layer 700′. The heat dissipation layer 800 may have a structure in which a metal layer 801 and a thermal conductive adhesive layer 803 are stacked. For an example, the metal layer 801 may be a plate-shaped metal material with a certain thickness. For another example, the metal layer 801 may be made of a metal material having a thin film shape. In particular, the metal layer 801 may be preferably formed of a metal material such as aluminum, which has excellent thermal conductivity in the horizontal surface direction (or planar surface direction).

The thermal conductivity adhesive layer 803 may be an adhesive layer made of the thermal conductive material TCM described in FIG. 6. For an example, the thermal conductive adhesive layer 803 may be made of a material including a filler and a silicon-based adhesive resin with the volume contents of 8:2 to 9:1. The filler may be made by mixing alumina particles (or powder) and silicon nitride particles (or powder) with a volume content of 8:2.

The driving elements may be attached on the bottom surface of the thermal conductivity adhesive layer 803. The driving elements may be attached one portion of the bottom surface of the thermal conductivity adhesive layer 803. For example, the source driving IC 410 and the circuit board 450 may be attached to the thermal conductivity adhesive layer 803. The timing controller 500 may be mounted on the bottom surface of the circuit board 450.

With this structure, the heat generated from the driving elements may be transferred to the metal layer 801 through the thermal conductivity adhesive layer 803, and diffused to the horizontal surface direction of the metal layer 801 and then discharged outside. In particular, the thermal conductivity adhesive layer 803 may have a much higher thermal conductivity than the first adhesive layer 302 and the second adhesive layer 304 made of a pressure-sensitive adhesive material, so the thermal conductivity adhesive layer 803 may quickly transfer the heat generated from the driving elements to the metal layer 801. Although some heats generated from the driving elements may be transferred to the substrate 110, these heats may be prevented from being transferred to the display layer 600 by the heat insulating layer 700′.

Further, the heat generated from the display layer 600 may be quickly discharged out of the top surface by the thermal conductive cover layer 703 disposed on the top surface of the display layer 600. Although some of heats may be transferred to the substrate 110, these heats may be prevented from being transferred to the driving elements by the heat insulating layer 700′.

According the fourth embodiment, the thermal conductive adhesive layer 803 disposed under the metal layer 801 may transfer the heat generated from the driving elements to the metal layer 801 very quickly, and then discharged outside. Furthermore, the thermal conductive cover layer 703 disposed on the display layer 600 may quickly discharge the heat generated from the display layer 600 outside. At the same time, the insulation property may be improved due to the first non-thermal conductive adhesive layer 702 and the second non-thermal conductive adhesive layer 704 so that the heats generated from the display layer 600 and the heats generated from the driving elements may not pass through the substate 110 and affect each other.

### Fifth Embodiment

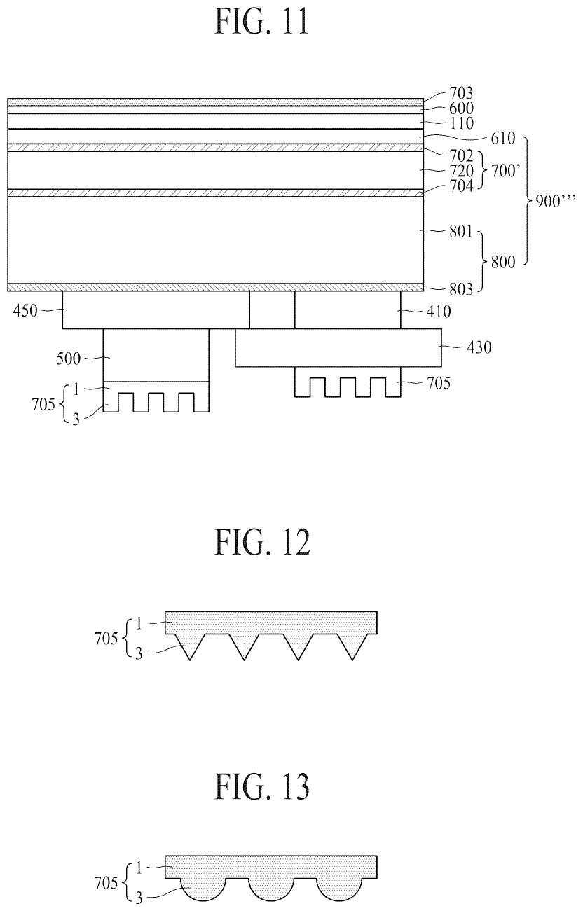

Referring to FIG. 11, a light emitting display device according to a fifth embodiment of the present disclosure will be explained. FIG. 11 is an enlarged cross-sectional view of square dotted area ‘X’ in FIG. 5, illustrating a structure of the light emitting display device according to a fifth embodiment of the present disclosure.

The light emitting display device according to the fifth embodiment may be very similar to the light emitting display device according to the fourth embodiment. The difference may be that the fifth embodiment may further include a heat dissipation element 705 may be attached to the driving elements 410, 430 and 500. The same description as the fourth embodiment may be not duplicated or simply explained.

Referring to FIG. 11, the light emitting display device according to the fifth embodiment of the present disclosure may comprise a substrate 110, a display layer 600, a thermal conductive cover layer 703, a protective layer 610, a heat insulating layer 700′ and a heat dissipation layer 800. Here, the protective layer 610, the heat insulating layer 700′ and the heat dissipation layer 800 may be configured to an underneath structure 900″′ supporting/protecting the substrate 110.

The display layer 600 may be formed on the top surface of the substrate 110. The thermal conductive cover layer 703 may be disposed on the top surface of the display layer 600. The thermal conductive cover layer 703 may be attached to have an area equal to or slightly larger than the display area AA so as to completely cover the display area AA of the display layer 600. For example, even though it is not shown in figures, the thermal conductive cover layer 703 may not be disposed on the pad portion 300 of the display layer 600 to which the flexible circuit film 430 is attached.

The protective layer 610 may be deposited on the bottom surface of the substrate 110. The heat insulating layer 700′ may be attached on the bottom surface of the protective layer 610. The heat insulating layer 700′ may include a first non-thermal conductive adhesive layer 702, a shock absorbing layer 720 and a second non-thermal conductive adhesive layer 704. The heat insulating layer 700′ may be disposed so that one surface of the first non-thermal conductive adhesive 702 is attached to the bottom surface of the protective layer 610. Further, the heat insulating layer 700′ may have a same size as the protective layer 610. The bottom surface of the first non-thermal conductive adhesive 702 may be attached on the entire top surface of the heat insulating layer 700′. The top surface of the first non-thermal conductive adhesive 702 may be attached on the entire bottom surface of the protective layer 610.

The heat dissipation layer 800 may be attached to one surface of the second non-thermal conductive adhesive layer 704 comprising the heat insulating layer 700′. Further, the heat dissipation layer 800 may have the same size as the second non-thermal conductive adhesive layer 704, and the bottom surface of the second non-thermal conductive adhesive layer 704 may be attached to the entire top surface of the heat dissipation layer 800. The heat dissipation layer 800 may have a structure in which a metal layer 801 and a thermal conductive adhesive layer 803 are stacked. The driving elements 410 and 450 may be attached to the thermal conductive adhesive layer 803.

The thermal conducting cover layer 703 and the thermal conductive adhesive layer 803 may be the film-type layers or the film-type adhesive layers including a thermal conductive material (TCM) described with FIG. 6. For an example, the thermal conducting cover layer 703 and/or the thermal conductive adhesive layer 803 may be made of a material including a filler and a silicon-based resin with the volume contents of 8:2 to 9:1. The filler may be made by mixing alumina particles (or powder) and silicon nitride particles (or powder) with a volume content of 8:2. After applying these materials, the film type thermal conducting cover layer 703 and/or the film type the thermal conductive adhesive layer 803 may be formed by curing. Otherwise, after forming as the adhesive film type, applying them on the proper surfaces.

The first non-thermal conductive adhesive 702 and the second non-thermal conductive adhesive 704 may be made of a non-thermal conductive material NTC described with FIG. 6. For an example, the first non-thermal conductive adhesive 702 and the second non-thermal conductive adhesive 704 may be made of a material including a filler and an acryl-based adhesive resin with the volume contents of 3:7 to 6:4. The filler may be made by mixing alumina particles (or powder) and silicon nitride particles (or powder) with a volume content of 2:8.

The heat dissipation element 705 may be attached to the driving elements 410 and 450. In detail, the bottom portion of the source driving IC 410 may be mounted on the flexible circuit film 430, and the top surface of the source driving IC 410 may be attached to the thermal conductive adhesive layer 803. Therefore, the heat dissipation element 705 may be disposed at the bottom surface of the flexible circuit film 430. In addition, the heat dissipation element 705 may be attached on the top surface of the timing controller 500 mounted at the circuit board 450.

The heat dissipation element 705 may be made of the thermal conductive material TCM explained with FIG. 6, and may be configured to have specific shape. For an example, the heat dissipation element 705 may be made by applying with a material including a filler and a silicon-based resin at a volume content of 8:2 to 9:1, curing and/or patterning. The filler may be made by mixing alumina particles (powder) and silicon nitride particles (powder) with a volume content of 8:2.

The heat dissipation element 705 may include a base portion 1 and a pattern portion 3. The base portion 1 may have a plate shape corresponding to the size of the driving elements 410 and 450. The pattern portion 3 may be formed to have a concave-convex shape. For an example, the concave-convex shape may have a cross-sectional shape of a square sawtooth shape. The pattern portion 3 having a concave-convex shape may have a larger surface area than flat shape, thereby increasing the area in contact with air. As a result, the heat generated from the driving elements 410 and 500 may be quickly discharged into the air.

FIG. 12 and FIG. 13 illustrate other examples of the heat dissipation element 705 having different shapes. FIG. 12 is a cross-sectional view illustrating a form of a heat dissipation element according to another example of the light emitting display device shown in FIG. 11. Referring to FIG. 12, the pattern portion 3 of the heat dissipation element 705 may have a cross-sectional shape of a triangular sawtooth shape.

FIG. 13 is a cross-sectional view illustrating a form of a heat dissipation element according to still another example of the light emitting display device shown in FIG. 11. Referring to FIG. 13, the pattern portion 3 of the heat dissipation element 705 may have a cross-sectional shape of semicircular sawtooth shape.

With this structure, the heat generated from the driving elements may be transferred to the metal layer 801 through the thermal conductivity adhesive layer 803, and diffused to the horizontal surface direction of the metal layer 801 and then discharged outside. In particular, the heats may be directly and quickly discharged outside by the heat dissipation element 705 attached on the surface of the driving elements. Meanwhile, the heats generated from the driving elements may be prevented from transferring to the display layer 600 by the heat insulating layer 700′. Further, the heat generated from the display layer 600 may be discharged out of the top surface through the thermal conductive cover layer 703 disposed on the top surface of the display layer 600. Although some of heats may be transferred to the substrate 110, these heats may be prevented from being transferred to the driving elements by the heat insulating layer 700′.

According to the fifth embodiment, the thermal conductive adhesive layer 803 disposed under the metal layer 801 may transfer the heat generated from the driving elements to the metal layer 801 very quickly, and then discharged outside. Furthermore, the heat generated from the driving elements may be quickly and directly discharged outside through the heat dissipation element 705. In addition, the thermal conductive cover layer 703 disposed on the display layer 600 may quickly discharge the heat generated from the display layer 600 outside. At the same time, the insulation property may be improved due to the first non-thermal conductive adhesive layer 702 and the second non-thermal conductive adhesive layer 704 so that the heats generated from the display layer 600 and the heats generated from the driving elements may not pass through the substate 110 and affect each other.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. A light emitting display comprising:
a substrate;
a display layer on the substrate;
a protective layer under the substrate;
a heat insulating layer under the protective layer;
a heat dissipation layer under the heat insulating layer; and
a driving element under the heat dissipation layer.

2. The light emitting display according to claim 1, wherein the heat insulating layer prevents first heat generated from the display layer from being transferred to the driving element, and prevents second heat generated from the driving element from being transferred to the display layer.

3. The light emitting display according to claim 1, wherein the heat dissipation layer discharges heat generated from the driving element outside through a horizontal surface direction of the substrate.

4. The light emitting display according to claim 3, wherein the heat insulating layer includes:
a metal layer under the heat insulating layer; and
a thermal conductive adhesive layer under the metal layer.

5. The light emitting display according to claim 4, wherein the thermal conductive adhesive layer transfers the heat generated from the driving element to the metal layer,
wherein the metal layer discharges the heat transferred from the thermal conductive adhesive layer outside along a horizontal surface direction of the substrate.

6. The light emitting display according to claim 4, wherein the metal layer includes aluminum, and
wherein the thermal conductive adhesive layer includes a filler and a silicon-based resin with a volume content ratio in a range of 8:2 to 9:1, the filler including aluminum particles and silicon nitride particles with a volume content ratio of 8:2.

7. The light emitting display according to claim 1, further comprising:
a thermal conductive cover layer on the display layer.

8. The light emitting display according to claim 7, wherein the thermal conductive cover layer includes a filler and a silicon-based resin with a volume content ratio in a range of 8:2 to 9:1, the filler including aluminum particles and silicon nitride particles with a volume content ratio of 8:2.

9. The light emitting display according to claim 1, wherein the heat insulating layer includes:
a first non-thermal conductive adhesive layer under the protective layer;
a shock absorbing layer under the first non-thermal conductive adhesive layer; and
a second non-thermal conductive adhesive layer under the shock absorbing layer.

10. The light emitting display according to claim 9, wherein each of the first non-thermal conductive adhesive layer and the second non-thermal conductive adhesive layer includes a filler and an acryl-based resin with a volume content ratio in a range of 3:7 to 6:4, the filler including aluminum particles and silicon nitride particles with a volume content ratio of 2:8.

11. The light emitting display according to claim 1, further comprising:
a thermal conductive cover layer on the display layer,
wherein the heat dissipation layer includes:
a metal layer under the heat insulating layer; and
a thermal conductive adhesive layer under the metal layer, and
wherein the heat insulating layer includes:
a first non-thermal conductive adhesive layer under the protective layer;
a shock absorbing layer under the first non-thermal conductive adhesive layer; and
a second non-thermal conductive adhesive layer under the shock absorbing layer.

12. The light emitting display according to claim 11, wherein each of the thermal conductive cover layer and the thermal conductive adhesive layer includes a filler and a silicon-based resin with a volume content ratio in a range of 8:2 to 9:1, the filler including aluminum particles and silicon nitride particles with a volume content ratio of 8:2, and
wherein each of the first non-thermal conductive adhesive layer and the second non-thermal conductive adhesive layer includes a filler and an acryl-based resin with a volume content ratio in a range of 3:7 to 6:4, the filler including aluminum particles and silicon nitride particles with a volume content ratio of 2:8.

13. The light emitting display according to claim 1, further comprising:
a heat dissipation element attached to the driving element.

14. The light emitting display according to claim 13, wherein the heat dissipation element includes a filler and a silicon-based resin with a volume content ratio in a range of 8:2 to 9:1, the filler including aluminum particles and silicon nitride particles with a volume content ratio of 8:2.

15. The light emitting display according to claim 13, wherein the heat dissipation element includes:
a base portion; and
a pattern portion on the base portion, the pattern portion including a plurality of patterns arrayed with a predetermined interval on the base portion.

16. The light emitting display according to claim 15, wherein the pattern portion includes a cross-sectional shape of any one shape of triangle, rectangle, and semicircle.
